(19) United States
(12) Patent Application Publication
(10) Pub. No.: US 2022/0406683 A1
(43) Pub. Date: Dec. 22, 2022

(54) IMMERSION COOLING PACKAGE

(71) Applicant: SEMICONDUCTOR COMPONENTS INDUSTRIES, LLC, Phoenix, AZ (US)

(72) Inventors: Seungwon IM, Seoul (KR); Oseob JEON, Seoul (KR); Michael J. SEDDON, Gilbert, AZ (US)

(73) Assignee: SEMICONDUCTOR COMPONENTS INDUSTRIES, LLC, Phoenix, AZ (US)

(21) Appl. No.: 17/664,482

(22) Filed: May 23, 2022

Related U.S. Application Data
(60) Provisional application No. 63/202,561, filed on Jun. 16, 2021.

(51) Int. Cl. H01L 23/44; H01L 21/48; H05K 7/20

(52) U.S. Cl. CPC H01L 23/44; H01L 21/4882; H05K 7/20927

(57) ABSTRACT

Implementations of a semiconductor package may include one or more semiconductor die embedded in a substrate; at least three pin fin terminals coupled to the substrate; at least one signal lead connector and a fixture portion coupled to the substrate; and a coating directly coupled to all surfaces of the substrate exposed to a coolant during operation. The fixture portion may be configured to be fastened to a fixture in an immersion cooling enclosure that may include the coolant.

### CROSS REFERENCE TO RELATED APPLICATIONS

This document claims the benefit of the filing date of U.S. Provisional Patent Application 63/202,561, entitled “Immersion Cooling Package” to Im et al., which was filed on Jun. 16, 2021, the disclosure of which is hereby incorporated entirely herein by reference.

### BACKGROUND

### 1. Technical Field

Aspects of this document relate generally to semiconductor packages, such as packages for semiconductor devices. More specific implementations involve packages for power semiconductor devices.

### 2. Background

Semiconductor packages work to enable electrical connections between a semiconductor die with other electrical components in a system. Semiconductor packages also have been devised that protect a semiconductor die from physical forces (impact, thermal stress, mechanical stress) and from environmental variables like humidity or light.

### SUMMARY

Implementations of a semiconductor package may include one or more semiconductor die embedded in a substrate; at least three pin fin terminals coupled to the substrate; at least one signal lead connector and a fixture portion coupled to the substrate; and a coating directly coupled to all surfaces of the substrate exposed to a coolant during operation. The fixture portion may be configured to be fastened to a fixture in an immersion cooling enclosure that may include the coolant.

Implementations of semiconductor packages may include one, all, or any of the following:

The one or more semiconductor die may be coupled in parallel when embedded in the substrate.

he one or more semiconductor die may be stacked when embedded in the substrate.

The at least three pin fin terminals may be a P terminal, N terminal, and an output terminal.

The N terminal and P terminal may be coupled to opposing sides of the substrate.

In various implementations of packages only a substrate may be included.

The at least three pin fin terminals may be six pin fin terminals and the six pin terminals may be a P terminal, a N terminal, a U output terminal, a V output terminal, and a W output terminal.

The package may be a traction inverter module.

Implementations of an immersion cooling system may include an immersion cooling enclosure including a coolant coupled with a cooling exchanger; a semiconductor package immersed in the coolant. The semiconductor package may include one or more semiconductor die embedded in a substrate; at least one pin fin terminal coupled to the substrate; at least one signal lead connector; a fixture portion coupled to the substrate; and a coating directly coupled to all surfaces of the substrate exposed to a coolant during operation.

Implementations of an immersion cooling system may include, one, all, or any of the following:

The fixture portion may be configured to be fastened to a fixture coupled with the immersion cooling enclosure.

The one or more semiconductor die may be coupled in parallel when embedded in the substrate.

The one or more semiconductor die may be stacked when embedded in the substrate.

The at least one pin fin terminal may be three pin fin terminals and where the three pin fin terminals may be a P terminal, N terminal, and an output terminal.

The N terminal and P terminal may be coupled to opposing sides of the substrate. system wherein only a substrate may be included in the semiconductor package.

The at least one pin fin terminals may be six pin fin terminals and where the six pin fin terminals may be a P terminal, a N terminal, a U output terminal, a V output terminal, and a W output terminal.

The semiconductor package may be a traction inverter module.

Implementations of a method of forming a semiconductor package may include embedding one or more semiconductor die in a substrate; coupling at least one pin fin terminal directly to a side of the substrate using a joint process; coupling at least one signal lead connector and a fixture portion to the substrate; and applying a coating directly over all surfaces of the substrate exposed to a coolant during operation.

Implementations of a method of forming a semiconductor package may include one, all, or any of the following:

Embedding the one or more semiconductor die further may include stacking two or more semiconductor die.

Embedding the one or more semiconductor die further may include electrically coupling two or more semiconductor die in parallel.

The foregoing and other aspects, features, and advantages will be apparent to those artisans of ordinary skill in the art from the DESCRIPTION and DRAWINGS, and from the CLAIMS.

### BRIEF DESCRIPTION OF THE DRAWINGS

Implementations will hereinafter be described in conjunction with the appended drawings, where like designations denote like elements, and:

FIG. 1 is a perspective view of an implementation of a semiconductor package placed in an immersion cooling enclosure;

FIG. 2 is a cross sectional view of an implementation of a semiconductor package placed in an immersion cooling enclosure;

FIG. 3 is a cross sectional view of an implementation of a semiconductor package with semiconductor die coupled in parallel;

FIG. 4 is a cross sectional view of an implementation of a semiconductor package with semiconductor die stacked one above another;

FIG. 5 is a side cross sectional view of an implementation of a substrate following embedding semiconductor die therein;

FIG. 6 is a cross sectional view of the substrate implementation of FIG. 5 following coupling three pin fin terminals using a joining process;

FIG. 7 is a cross sectional view of the package implementation of FIG. 7 following coupling of terminals with the three pin fin terminals; and

FIG. 8 is a cross sectional view of the package implementation of FIG. 7 following application of a coating to the exposed substrate surfaces.

### DESCRIPTION

This disclosure, its aspects and implementations, are not limited to the specific components, assembly procedures or method elements disclosed herein. Many additional components, assembly procedures and/or method elements known in the art consistent with the intended semiconductor packages will become apparent for use with particular implementations from this disclosure. Accordingly, for example, although particular implementations are disclosed, such implementations and implementing components may comprise any shape, size, style, type, model, version, measurement, concentration, material, quantity, method element, step, and/or the like as is known in the art for such semiconductor packages, and implementing components and methods, consistent with the intended operation and methods.

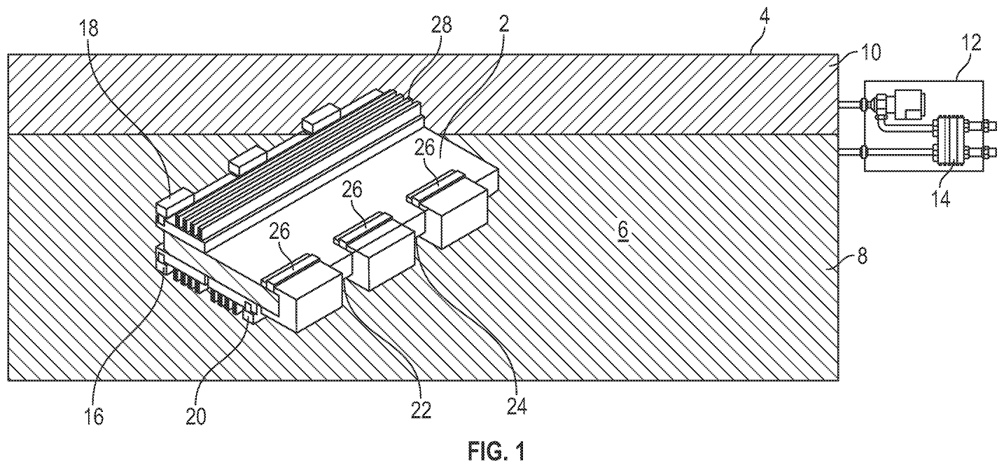

Referring to FIG. 1, an implementation of a semiconductor package 2 is illustrated placed within an immersion cooling enclosure 4 that includes a coolant 6 therein. As illustrated, the immersion cooling enclosure 4 includes both liquid phase coolant 8 and vapor phase coolant 10 in this implementation. However, in other implementations, the coolant 6 may be only liquid phase in the immersion cooling enclosure 4. As used herein, “immersion cooling” includes where at least a portion of the semiconductor package is immersed in a liquid phase of the coolant and thus includes situations where single phase or two phase coolant is employed in an immersion cooling enclosure. In various implementations, the immersion cooling enclosure 4 is included as part of an electronic system, such as, by non-limiting example, a car battery, an electric motor, a vehicle, or any other electronic system employing semiconductor die. The immersion cooling enclosure 4 may be self-contained and a closed system without an outlet relying on ambient or external forced convection cooling of the outer surface of the enclosure to remove heat transferred from the coolant 6 (for both two phase and single phase coolant situations). In other implementations, the immersion cooling enclosure 4 may be coupled with a cooling exchanger which receives heated coolant 6 from the interior of the enclosure 4, removes heat therefrom, and then cycles the cooled coolant back to the immersion cooling enclosure. As illustrated in FIG. 1, a cooling exchanger 12 is illustrated that receives vaporized coolant 10 and then condenses it using heat exchanger 14 to return liquid coolant 8 to the enclosure 4. In other implementations, however, the cooling exchange may only receive and cool liquid coolant from the immersion cooling enclosure even where two phases of the coolant are present in the enclosure. A wide variety of enclosure types and cooling exchange types may be constructed using the principles disclosed in this document. In particular implementations, the coolant used may be a chemically inert coolant. In other implementations, the coolant used may be a dielectric fluid. In some implementations, the coolant may be one of the inert and dielectric coolants marketed under the tradename FLUORINERT by 3M of St. Paul, Minn.

As illustrated in FIG. 1, the semiconductor package illustrated is a traction inverter designed to convert direct current electricity from a battery to alternating current electricity used to drive an electric motor. The principles disclosed herein, however, can be used to form semiconductor packages for many other electronic device types. In this package implementation, at least six pin fin terminals are included that correspond with the terminals of the electric motor: P terminal 16, N terminal 18, U terminal 20, V terminal 22, and W terminal 24. Signal lead connectors 26 are also included in this package. During operation, corresponding electrical cables (not shown for purposes of illustration in FIG. 1) will be connected to each of the terminals and signal lead connectors to allow the package to be electrically connected to an electrical motor. The pin fin terminals include multiple fins (pin fins in this case) that extend into the coolant and correspondingly increase the surface area of each terminal to increase heat transfer from the semiconductor package to the coolant. While the use of straight fins 28 with the pin fin terminals is illustrated in FIG. 1, various implementations may include a wide variety of fins and other projection types, such as, by non-limiting example, pins, cones, frustoconical shapes, rectangular protections, curved projections, or any other three dimensional fin or pin shape.

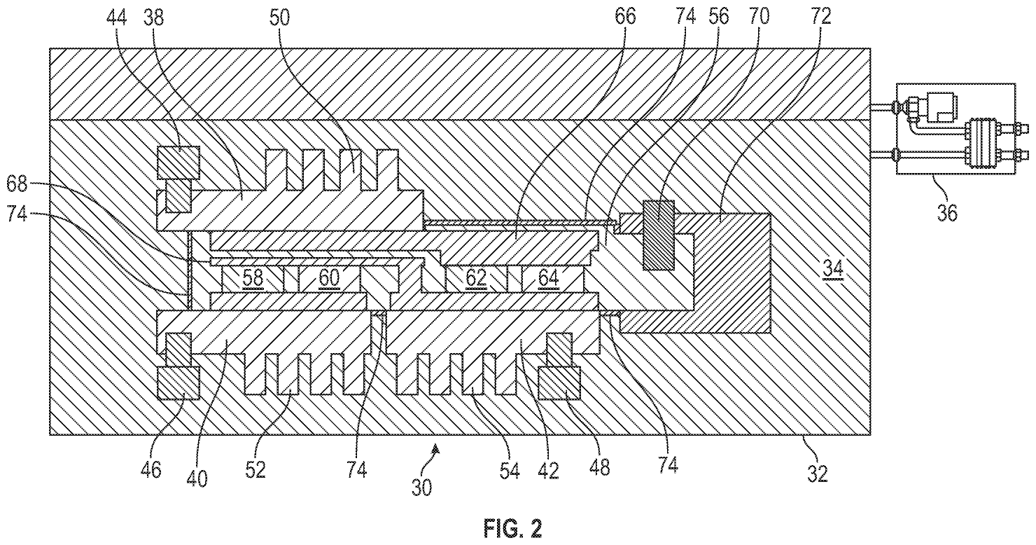

Referring to FIG. 2, a side cross sectional view of a semiconductor package 30 in immersion cooling enclosure 32 is illustrated. Immersion cooling enclosure 32 operates in a two phase mode with coolant 34 along with cooling exchanger 36 that functions similarly to the implementation illustrated in FIG. 1. Here the internal structure of the semiconductor package 30 is illustrated that shows N pin fin terminal 38, P pin fin terminal 40, and output pin fin terminal 42. Each of the pin fin terminals 38, 40, 42 includes terminal portions 44, 46, 48 designed to couple with an electrical cable which is coupled with fin portions 50, 52, 54. Fin portions 50, 52, 54 are directly coupled through a joint/bond (that includes the associated bonding material) to substrate 56. Substrate 56 includes four semiconductor die 58, 60, 62, 64 embedded in the material of the substrate itself along with corresponding traces 66, 68 that electrically couple the die 58, 60, 62, 64 with each of the corresponding fin portions 50, 52, 54. An additional signal lead connector 70 is coupled at an end of the substrate 56 adjacent to fixture portion 72 which is designed to allow for the entire package 30 to be coupled into a fixture within the immersion cooling enclosure 32. The particular shapes of the various terminal portions 44, 46, 48, signal lead connector 70, and fixture portion 72 are determined by the particular electrical cable connector used or fixture structure used to couple with the fixture portion 72. A wide variety of connector types and fixture coupling structures may be employed in various implementations and those of ordinary skill in the art will readily be able to select the appropriate terminal, lead connector, and fixture portion types and structures using the principles disclosed in this document.

In one set of implementations, the material of the substrate 56 may be any of a wide variety of material types used for circuit boards, including, by non-limiting example, FR1, FR2, FR4, FR5, FR6, G-10, G-11, alumina, glass-reinforced epoxy laminate, laminates, insulated metal substrates, polyimide foil, or any other circuit board material type capable of embedding semiconductor die therein. In another set of implementations, the material of the substrate may be a direct bonded copper (DBC) substrate. In yet other implementations, the substrate may be an insulated metal substrate (IMS). In still other implementations, the substrate may be a ceramic substrate. Because portions of the substrate 56 remain exposed even after the coupling of the pin fin terminals 38, 40, 42 thereto, a coating 74 is coupled to the outer surface of the substrate 56. The coating 74 can provide a large number of effects, such as, by non-limiting example, corrosion protection; ion gettering to extend longevity; physical protection during assembly; mechanical protection from coolant flow across the surface; particle/flake protection from particles from the enclosure, package, and/or assembly debris; and other positive effects resulting from protection of the material of the substrate 56 from the coolant 34.

While the coating 74 is illustrated in FIG. 2 as being applied to all exposed surfaces of the substrate 56, in other implementations, one, all, or any number of the surfaces/sides of the substrate 56 may be coated. The use of the coating 74 may also allow for protection of wirebonds formed on/to the substrate 56 as the coating may fully cover the wirebonds and mechanically and physically protect them from coolant flow and particles. The use of the coating may also assist with repairing of any components of the package during assembly as components can be tested individually first prior to full assembly. While a single layer of coating material is illustrated in FIG. 2, multiple layers of coating material(s) may be applied in various implementations each made of the same or different materials. The coating 74 may be formed of any of a wide variety of materials, including, by non-limiting example, epoxies, novolac resins, polymer films, aluminum oxide, titanium nitride, mold compound, any combination thereof, or any other material capable of being applied to the substrate and resistant to the coolant material. In particular implementations, the ability to use aluminum oxide and/or titanium nitride as the coating may result in a thin film that provides adequate protection in the environment of the immersion cooling enclosure while facilitating additional heat transfer from the substrate itself. For example, where the film is formed of aluminum oxide and/or titanium nitride, the film thickness may be, by non-limiting example, less than about 5 microns, between about 1 micron to about 5 microns, between about 1.5 microns to about three microns.

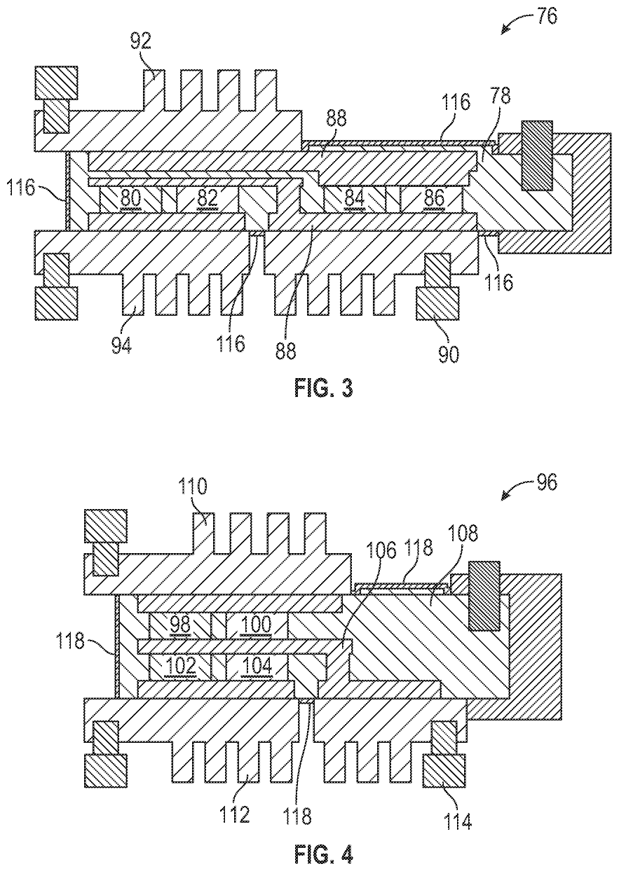

A wide variety of configurations and types of semiconductor die and traces may be utilized in various substrate implementations. Referring to FIG. 3, a semiconductor package 76 is illustrated that includes a substrate 78 that contains a first pair of an integrated-gate bipolar transistor (IGBT) 80 and a diode 82 coupled electrically in parallel with a second pair of an IGBT 84 and diode 86 through traces 88 to output terminal 90. Here the emitter and anode of the first IGBT/diode pair 80, 82 are coupled with the collector and cathode of the second IGBT/diode pair 84, 86 by the central trace of the traces 88. The ability to electrically couple the die in parallel allows for the package to be made more compactly and for the first IGBT/diode pair 80, 82 to be sandwiched between two heat sinks in the form of pin fin terminals 92, 94. This may allow for increased heat transfer for the first IGBT/diode pair 80, 82 compared to the heat transfer from the second IGBT/diode pair 84, 86. This configuration may be desirable where increased heat transfer is needed for one or more of the semiconductor die relative to other die in the substrate and/or where a particular form factor for the semiconductor package is desired.

FIG. 4 illustrates a semiconductor package 96 implementation where a first IGBT/diode pair 98, 100 is coupled in a stacked configuration above a second IGBT/diode pair 102, 104. Electrically, the collector and cathode of the first IGBT/diode pair 98, 100 are coupled to the emitter and anode of the second IGBT/diode pair 102, 104 via central trace 106. In this configuration, the first IGBT/diode pair 98, 100 and the second IGBT/diode pair 102, 104 are electrically coupled in series. Here, this design places all of the semiconductor die embedded in the substrate 108 between the two pin fin terminals 110, 112, thereby ensuring that the cooling effect available to each is substantially equivalent, including the cooling effect of the central trace 106 which may act as a heat pipe to the output pin fin terminal 114.

In both the implementation illustrated in FIG. 3 and FIG. 4 a coating 116, 118 is applied over the exposed portions of the substrates 78, 108. These coatings 116, 118 may be any coating material disclosed in this document. A wide variety of embedded die configurations may be constructed in combination with the structure of the pin fin terminals using the principles disclosed in this document. Any of a wide variety of semiconductor die may be employed as well, including, by non-limiting example, power semiconductor die, processors, memory, IGBTs, diodes, rectifiers, metal-oxide field effect transistors (MOSFETs), gallium arsenide devices, high-electron-mobility transistors (HEMTs), passive components (capacitors, resistors, inductors, etc.) or any other semiconductor device or component. This process of embedding the die and forming the traces also works to couple the various die in parallel or stack the die above each other. In various method implementations, one die may be embedded, or more than one die may be embedded.

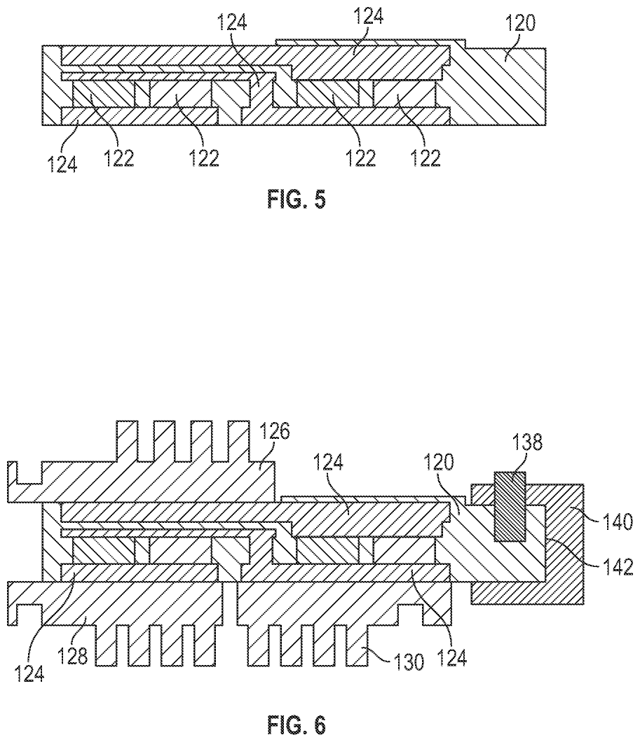

Various methods of forming semiconductor packages like those disclosed in this document involve processes of forming substrates and fastening components thereto. Referring to FIG. 5, a cross sectional view of a substrate 120 implementation is illustrated following the process of embedding four semiconductor die 122 therein and forming traces 124 to interconnect the die 122. The process of embedding the die and forming the traces may involve any of the following, by non-limiting example, laminating the die into one or more layers of circuit board material, laminating the traces, patterning and etching the traces, molding the die with the circuit board material, or any other processing step for embedding the die and related components and/or forming the traces in the material of the circuit board. The ability to embed the die into the material of the substrate 120 enables the use of the semiconductor package in an immersion cooling enclosure because the die are not separately exposed to the coolant but protected by the material of the substrate. This technique may ensure the package has a desired degree of reliability and/or longevity in the immersion cooling enclosure.

Referring to FIG. 6, the substrate 120 of FIG. 5 is illustrated following coupling of three fin portions 126, 128, 130 to opposing sides of the substrate 120. The fin portions are pin fins like those disclosed in this document, but the fin portions may be any other type disclosed in this document. The process of coupling the fin portions may involve any of a wide variety of techniques, including, by non-limiting example, soldering, bonding, brazing, gluing, thermocompression bonding, joining using a solder, joining using an attach film, joining using an adhesive, or any other method for coupling two materials together to facilitate heat transfer/electricity therethrough. As visible in FIG. 6, the three fin portions 126, 128, 130 make electrical contact with traces 124. In this way, the fin portions are able to double as electrical connectors along with functioning as heat transfer devices. The use of an immersion cooling enclosure with a dielectric coolant ensures that during operation these electrically energized fin portions do not have the ability to short or otherwise conduct electricity to undesired structures/persons. The materials used for the three fin portions may be any of a wide variety of thermally conductive materials including, by non-limiting example, metals, metal alloys, alumina, copper, copper alloys, aluminum, aluminum alloys, or any other thermally conductive material.

FIG. 6 also illustrates the coupling of signal lead connector 138 into the material of the substrate 120 thereby mechanically and electrically coupling signal traces (not illustrated in the cross sectional view of FIG. 6) with the signal lead connector 138. Multiple signal lead connectors may be coupled with the substrate 120 in various implementations depending on the number of signal traces included in the substrate. Also, fixture portion 140 is illustrated coupled to/around/into end 142 of the substrate 120. The particular signal lead connectors and fixture portions coupled to the substrate at this point may be any disclosed in this document depending on the electrical connector type for the electrical cables and the fixture type used to support the package in the immersion cooling enclosure.

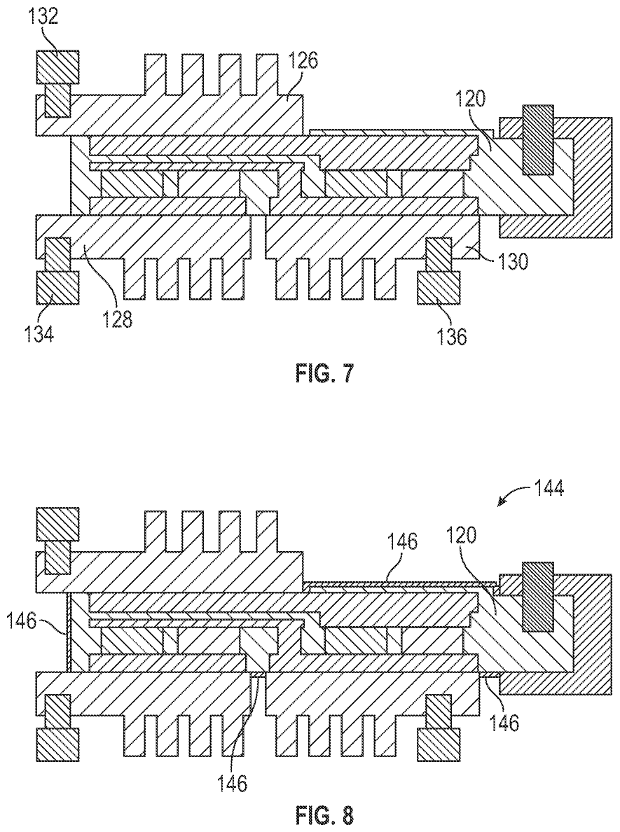

Referring to FIG. 7, the substrate 120 of FIG. 6 is illustrated following coupling of terminals 132, 134, 136 into the three fin portions 126, 128, 130. The coupling may take place using a wide variety of methods, including, by non-limiting example, soldering, screwing, bonding, adhering, clipping, riveting, or any other method of coupling two metallic pieces together. In the implementation illustrated in FIG. 7, terminal 132 is an N terminal, terminal 134 is a P terminal, and terminal 130 is an output terminal. The particular shape and type of each terminal 132, 134, 136 depend on the type of electrical cable that will be used to connect to each terminal which may be any disclosed in this document.

Referring to FIG. 8, a view of the completed package 144 is illustrated following application of coating 146 over the exposed portions of the substrate 120. The material of the coating 146 may be any disclosed in this document. In certain method implementations, where the coating has two or more layers, multiple application steps may be sequentially carried out (along with a corresponding number of curing/drying steps). For example, a gel-type material may be applied in a first coating process followed by application of a mold compound through a molding process to form a two layer coating material. In some implementations, the application process for the coating may be a printing process. In other implementations, the application process may be a molding process. In other implementations, the coating may be applied using, by non-limiting example, spraying, dipping, dispensing, chemical vapor deposition, sputtering, physical vapor deposition, film application, or any other method for forming a layer of material over a substrate.

In various semiconductor package implementations, while the pin fins illustrated herein are illustrated as being suspended in the coolant, one or more of the pin fin terminals may contact the wall(s) of the immersion cooling enclosure. In some, the pin fin terminals may be directly coupled with/through the walls through screwing/bonding; in others the pin fin terminal(s) may merely be in physical contact with the wall(s) of the immersion cooling enclosure. In such implementations, where sufficient mechanical support is available by/against the walls of the immersion cooling enclosure using the pin fins, no fixture may be used to further secure the semiconductor package therein. In such implementations, no fixture portion may be included/coupled with the substrate. Also, in such implementations, additional conductive heat transfer is possible to the wall(s) of the immersion cooling enclosure. A wide variety of configurations of pin fin terminals for various semiconductor package implementations that involve contact with/bonding with the wall(s) of the immersion cooling enclosure may be devised using the principles disclosed in this document.

In places where the description above refers to particular implementations of semiconductor packages and implementing components, sub-components, methods and sub-methods, it should be readily apparent that a number of modifications may be made without departing from the spirit thereof and that these implementations, implementing components, sub-components, methods and sub-methods may be applied to other semiconductor package types.

What is claimed is:

1. A semiconductor package comprising:
one or more semiconductor die embedded in a substrate;
at least three pin fin terminals coupled to the substrate;
at least one signal lead connector and a fixture portion coupled to the substrate; and
a coating directly coupled to all surfaces of the substrate exposed to a coolant during operation;
wherein the fixture portion is configured to be fastened to a fixture in an immersion cooling enclosure that comprises the coolant.

2. The package of claim 1, wherein the one or more semiconductor die are coupled in parallel when embedded in the substrate.

3. The package of claim 1, wherein the one or more semiconductor die are stacked when embedded in the substrate.

4. The package of claim 1, wherein the at least three pin fin terminals are a P terminal, N terminal, and an output terminal.

5. The package of claim 4, wherein the N terminal and P terminal are coupled to opposing sides of the substrate.

6. The package of claim 1, wherein only a substrate is included.

7. The package of claim 1, wherein the at least three pin fin terminals are six pin fin terminals and the six pin terminals are a P terminal, a N terminal, a U output terminal, a V output terminal, and a W output terminal.

8. The package of claim 1, wherein the package is a traction inverter module.

9. An immersion cooling system comprising:
an immersion cooling enclosure comprising a coolant coupled with a cooling exchanger;
a semiconductor package immersed in the coolant, the semiconductor package comprising:
one or more semiconductor die embedded in a substrate;
at least one pin fin terminal coupled to the substrate;
at least one signal lead connector and a fixture portion coupled to the substrate; and
a coating directly coupled to all surfaces of the substrate exposed to a coolant during operation;

10. The system of claim 9, wherein the fixture portion is configured to be fastened to a fixture coupled with the immersion cooling enclosure.

11. The system of claim 9, wherein the one or more semiconductor die are coupled in parallel when embedded in the substrate.

12. The system of claim 9, wherein the one or more semiconductor die are stacked when embedded in the substrate.

13. The system of claim 9, wherein the at least one pin fin terminal is three pin fin terminals and where the three pin fin terminals are a P terminal, N terminal, and an output terminal.

14. The system of claim 13, wherein the N terminal and P terminal are coupled to opposing sides of the substrate.

15. The system of claim 9, wherein only a substrate is included in the semiconductor package.

16. The system of claim 9, wherein the at least one pin fin terminals is six pin fin terminals and where the six pin fin terminals are a P terminal, a N terminal, a U output terminal, a V output terminal, and a W output terminal.

17. The system of claim 9, wherein the semiconductor package is a traction inverter module.

18. A method of forming a semiconductor package comprising:
embedding one or more semiconductor die in a substrate;
coupling at least one pin fin terminal directly to a side of the substrate using a joint process;
coupling at least one signal lead connector and a fixture portion to the substrate; and
applying a coating directly over all surfaces of the substrate exposed to a coolant during operation.

19. The method of claim 18, wherein embedding the one or more semiconductor die further comprises stacking two or more semiconductor die.

20. The method of claim 18, wherein embedding the one or more semiconductor die further comprises electrically coupling two or more semiconductor die in parallel.
